(19) United States
(12) Patent Application Publication
(10) Pub. No.: US 2005/0073448 A1
(43) Pub. Date: Apr. 7, 2005

(54) Prioritization policy method for selectively compressing image data on a window-by-window basis

(76) Inventors: Mark J. Buxton, Chandler, AZ (US); Brent Baxter, Hillsboro, OR (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 10/680,499

(22) Filed: Oct. 6, 2003

(51) Int. Cl. H03M 7/30

(52) U.S. Cl. 341/87; 341/51

(57) ABSTRACT

A method, machine readable medium, and system is disclosed. In one embodiment the method comprises assigning a priority level to a window in a windows-based environment and compressing the image data residing in the window if the priority level of the window falls below a predetermined threshold priority level.

### BACKGROUND

There are a great variety of images displayed on a given personal computer screen with today's range of applications. In a windows-based environment many of these images, which originate from a variety of applications, can be visible on a computer screen at the same time. In many instances this causes memory bandwidth issues for the computer because so much information is displayed at once. One window display might have a movie playing, another could have a word processing program with text, and yet another could have a web browser. All of these windows could be visible simultaneously but in many cases the user is focusing his concentration on one window over the others. Additionally, new personal computer operating system software is being designed to produce interesting visual effects such as transparency and animated window transitions using 3D rendering techniques to compose the desktop image. These techniques, as well as the content displayed in each window, unfortunately increase the memory bandwidth required to maintain a smooth multi-windowed desktop that the user desires.

Image compression is a well known concept to conserve bandwidth and minimize the amount of data used when an image is displayed, copied, or moved in a computer system. Many images, such as continuous-tone photos or pages of text, can be compressed effectively because regions of the image with the same colors can be easily compressed into smaller pieces of data; however, image compression does have associated detractions. For one, compressing image data and then decompressing it for display on the screen causes significant added computational overhead to the computer. The computer no longer just has to display the image, but it needs to add the compression and decompression steps for any given image and those steps take up valuable CPU cycles. Furthermore, when decompressing image data that was previously compressed there are occasional visible compression-process artifacts that degrade the quality of the original image.

Thus, there is a need in a windows-based environment for an effective method to selectively compress image data on a per window basis to maximize the efficiency of the processor's compute power and to minimize the artifacts visible by the process.

### BRIEF DESCRIPTION OF THE DRAWINGS

The present invention is illustrated by way of example and is not limited by the figures of the accompanying drawings, in which like references indicate similar elements, and in which:

FIG. 1 illustrates a functional flowchart of one embodiment of the invention.

FIG. 2 illustrates an example the determination of the compression policy priority level for each of a group of windows displayed on a desktop in one embodiment of the present invention.

FIG. 3 illustrates a step-by-step process of the determination of whether to compress a given image displayed in a given window.

### DETAILED DESCRIPTION

A method in a windows-based environment for selectively compressing image data on a per window basis by assigning each window a compression priority level based on window location and window content is described. In the following description, numerous specific details are set forth. However, it is understood that embodiments may be practiced without these specific details. In some instances, well-known elements, protocols, and file types such JPEG, MPEG, and Bitmap have not been discussed in special detail in order to avoid obscuring the present invention.

Reference throughout this specification to “one embodiment” or “an embodiment” indicate that a particular feature, structure, or characteristic described in connection with the embodiment is included in at least one embodiment. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

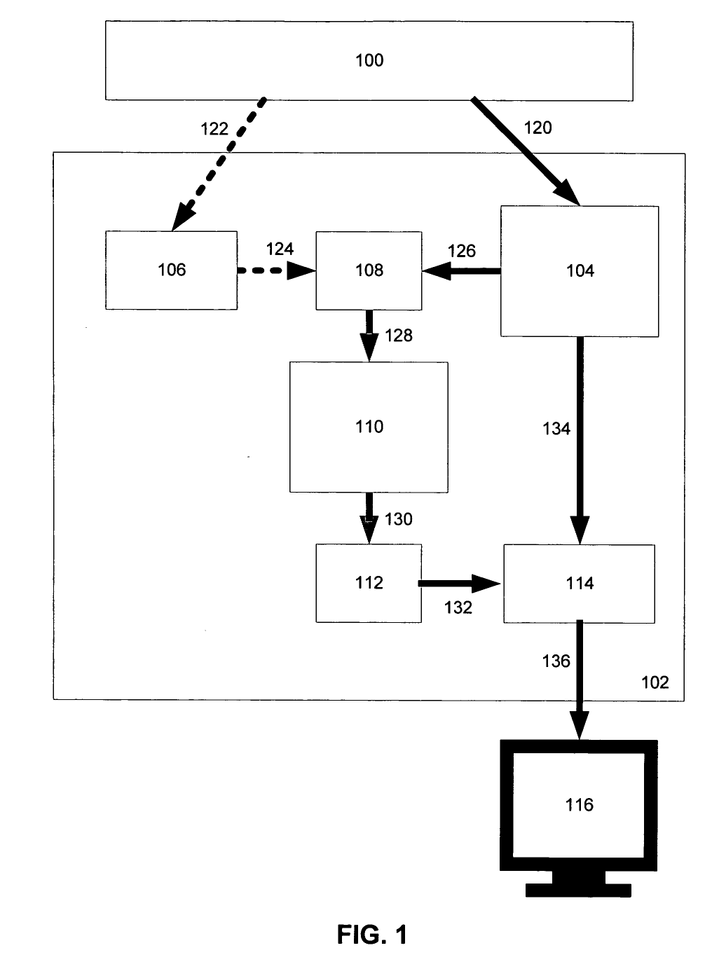

FIG. 1 illustrates a functional flowchart of one embodiment of the invention. A software application 100 is running in a windows environment within a given window. It sends image data 120 to the graphics subsystem 102. In one embodiment the graphics subsystem can be implemented entirely in hardware, in another embodiment the graphics subsystem can be implemented in a combination of hardware and software. The software application 100 also sends a content change notification 122 to the graphics subsystem 102 when any changes are made to the displayed content. The application may store data in either in compressed or uncompressed form. Regardless, the window memory 104 may experience further compression.

In one embodiment, the image data 120 sent from the software application 100 is stored in uncompressed window memory 104 within the graphics subsystem 102. A compression policy algorithm 106 residing within the graphics subsystem 102 receives as input a content change notification 122 used to determine whether or not the new content being displayed in the window should be compressed. In another embodiment the content change notification can be triggered internally, by the graphics driver or hardware, upon noting that memory bandwidth or some other resource is becoming scarce. The compression decision 124 whether to compress or not compress the image data in the uncompressed window memory 104 is sent to the compressor 108.

If a determination is made to compress the image data the compressor 108 pulls the image data information 126 from the uncompressed window memory 104. The compressor 108 then compresses the image data and sends it 128 to the compressed window memory 110. In one embodiment of the present invention the compressed and uncompressed memory consist of the same general memory that can be used to store images in either the compressed or uncompressed form. In another embodiment the memory where the compressed image data is stored is separate from the memory that stores the uncompressed image data. When the image data is to be displayed the decompressor 112 pulls the image data information 130 from the compressed window memory 110 and decompresses the data into a viewable image which is delivered 132 to the rendering engine 114 to compose the data into a desktop image and sent 136 to the display 116. De-compression is needed whenever an animation effect causes a compressed image component to change, move, assume a new shape or become transparent.

If a determination is made to not compress the image data the image data is just stored unmodified in the uncompressed window memory 104. When the uncompressed image data is to be displayed the image data can be sent 134 directly from the uncompressed window memory 104 to the rendering engine 114 to compose the data into a desktop image and sent 136 to the display 116.

The image data 120 originating from the software application 100 has many characteristics associated with it such as the size of the image displayed, whether the image is static or is animated, etc. In one embodiment multiple software applications are running on the same system simultaneously and each one is displaying a window with image data. For each window the compression policy algorithm must determine whether or not to compress the image data for each open window. In one embodiment there are many factors which are used to determine whether to compress each window's image data. Image types that make a window a candidate for compression include: surface textures for 3D graphical objects, 2D continuous-tone imagery, and 2D text and planar graphics data among others.

Compressing image data takes up CPU cycles and also will potentially create artifacts on certain images. Thus, a computer system should only begin image data compression when there is a memory bandwidth shortfall. Otherwise, not compressing image data is preferred due to lack of image artifacts and fewer CPU cycles needed for overhead. In one embodiment of the present invention the memory bandwidth is monitored in real-time and only once the memory bandwidth requirement cannot be met using uncompressed image data will the compression policy algorithm initiate data compression. In another embodiment of the invention the individual desktop image components are compressed on a prioritized window-by-window basis by comparing any bandwidth shortfall against a prediction of the bandwidth savings expected from using compressed data for that window. The compression policy algorithm can use a set of priority levels to determine if the bandwidth savings of a given compression candidate window will justify the compression process. The compression policy algorithm will use a number of priority factors associated with each candidate window to determine whether or not to compress the image data in each candidate window.

In one embodiment of the present invention the compression policy algorithm will take into account the location of the window on the desktop as one priority factor. This can include a determination of what percentage of the window is visible. A background window that is 70% covered by other windows could be a good candidate for compression considering focus is not likely directed at that particular window because the user cannot see the majority of its contents. Thus, a background window usually requires the least image quality.

In another embodiment of the present invention the compression policy algorithm can focus on the content within the window as a priority factor. A static window with a continuous tone will be suitable for a much higher compression ratio than a window with live video. The higher compression ratio translates directly into memory bandwidth savings because less data is transferring to and from memory. Windows with animations and rapid motion have a high image compression priority because motion makes image compression artifacts difficult to see. Windows containing continuous-tone imagery have a high image compression priority because continuous tones mask most image compression artifacts. Windows with little or no motion have a lower image compression priority because image compression artifacts may be more visible in static images such as JPEGs or bitmaps. Static windows containing data subject to close examination such as the active window have lower image compression priority because a user might not want or permit compression for the active window. Windows that change rapidly have lower image compression priority because compression overhead may outweigh benefits. Windows containing live or recorded video, such as an MPEG video have low image compression priority because compression overhead may make it impossible to display live video.

In another embodiment of the present invention the compression policy algorithm can focus on the size of the window as a priority factor. A large window will have higher compression overhead that may outweigh the benefits of compression, whereas a small window would be a better candidate because of the lower overhead.

In yet another embodiment of the present invention the compression ratio itself can be varied by the compression policy algorithm. A given compression algorithm can trade compression ratio for more prominent artifacts, allowing the visibility of compression artifacts to be balanced against available memory bandwidth. Additionally, a variable compression ratio will allow for computers with more processing power to give more compute cycles to aggressively compress image data whereas slower computers can less aggressively compress image data.

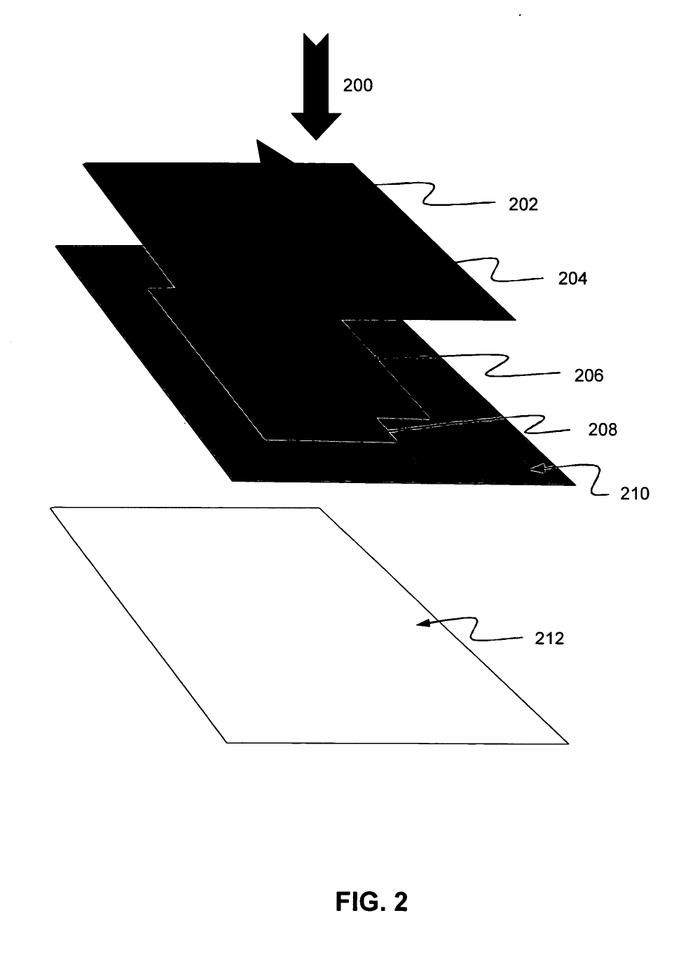

FIG. 2 illustrates an example of the determination of the compression policy priority level for each of a group of windows displayed on a desktop in one embodiment of the present invention. In one embodiment there are five windows open on a desktop 212 for the compression policy algorithm to determine what images to compress and not compress. In this particular figure the user has a bird's eye view and is looking down at the windows and the desktop from the top position 200. The images on background windows are usually less sensitive to quality degradations than foreground windows, therefore the window the furthest in the background 210 would be the first candidate for compression in this embodiment because image artifacts from compression would likely not be noticed. The second candidate window for compression in this embodiment would be a static text window 206, also in the background, that could potentially allow for a high compression ratio and good memory bandwidth savings. The third candidate for compression would be a window displaying a continuous tone image 208 due also to both high compression ratios for those image types and the background location of the window. The fourth candidate in this embodiment would be a Microsoft Powerpoint window 204. This window is a low priority because it is the active window and thus in prime focus where a user is most likely to concentrate his attention. The primary focus window is not always a good candidate for compression because the user would like to see very few compression artifacts if any, although, a Powerpoint slide, containing text would likely be amenable to a high compression ratio just like a static text window. The final window in this embodiment that is the least likely to be compressed is an animated window 202. This window is a bad candidate because continuous animation allows for a low compression ratio and therefore a low savings of memory bandwidth.

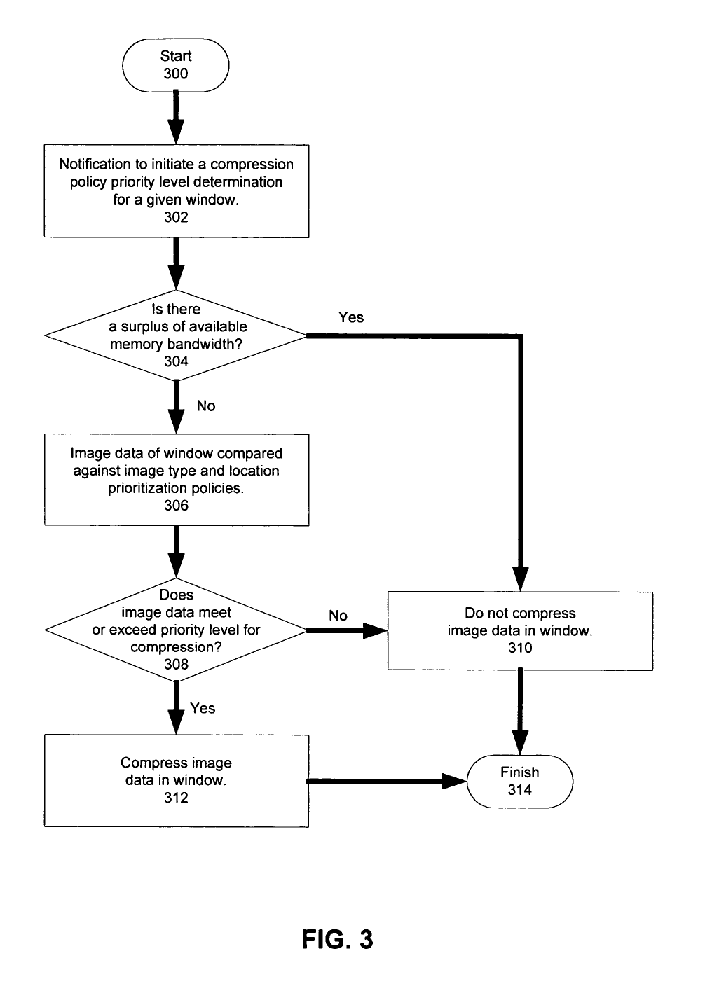

FIG. 3 illustrates a step-by-step process of the determination of whether to compress a given image displayed in a given window. At the start 300 the compression policy algorithm is notified by a system event that a compression policy priority level determination is needed for a given window 302. Examples of events that warrant a priority level determination for a window include the redraw of the display, the passage of time, the relative repositioning of the window, and the window initiating a change of the displayed image among others. The next step of the algorithm determines if excess memory bandwidth or other critical system resources are available so compression is not necessary 304. If there is extra memory bandwidth the algorithm will not compress the image data 310 and the process ends 314. Otherwise, if there is no extra bandwidth then the image data of the window is compared against image type and location prioritization policies 306. In this step the compression policy algorithm will determine what type of image is being displayed such as a static text image, an animation, or a continuous-tone image among others. The compression policy algorithm also determines where the window is located on the desktop and how much of the window is in view to the user. This information is fed into the compression policy algorithm and the output is a priority level associated with whether to compress the image. During the next step the algorithm determines whether or not the determined priority level meets or exceeds the priority level to compress the image 308.

The threshold priority level that is compared against can be determined in a number of ways. In one embodiment the threshold priority level is preprogrammed into the machine by the user. In another embodiment the compression policy algorithm determines the threshold priority level based on the speed of the CPU. In yet another embodiment the compression policy algorithm determines the threshold priority level based on the type of CPU or graphics subsystem. In yet another embodiment the compression policy algorithm determines the threshold priority level based on a combination of these factors among others.

If the image data meets or exceeds the threshold priority level for compression the algorithm tells the compressor to compress the image data 312. If the image data falls below the threshold priority level the algorithm tells the compressor not to compress the image data 310. At this point the image data compression determination is complete and the process is finished 314.

Thus, a method in a windows-based environment to selectively compress image data on a per window basis is disclosed. Although the invention has been described particularly with reference to the figures, it may appear in any number of systems. It is further contemplated that many changes and modifications may be made by one of ordinary skill in the art without departing from the spirit and scope of the disclosed invention.

1. A method, comprising:
assigning a priority level to a window in a windows-based environment; and
compressing the image data residing in the window if the priority level of the window falls below a predetermined threshold priority level.

2. The method of claim 1 wherein compressing the image data residing in the window further comprises:
measuring the memory bandwidth requirement for a device where the windows-based environment resides; and
compressing image data only if the memory bandwidth requirement for the device cannot be met using uncompressed image data for all currently open windows.

3. The method of claim 1 wherein compressing the image data residing in the window further comprises adjusting the compression ratio of the image data according to the image quality priority level.

4. The method of claim 1 wherein compressing the image data residing in the window further comprises adjusting the compression ratio of the image data according to the displayed resolution of the window.

5. The method of claim 1 wherein assigning a priority level to a window further comprises:
determining where the window resides on the desktop;
determining what image content resides within the window; and
setting a priority level for the window based on the determinations.

6. The method of claim 5 wherein determining where the window resides on the desktop further comprises determining whether the window is the active window or an inactive window.

7. The method of claim 5 wherein determining where the window resides on the desktop further comprises determining whether the window is located in the foreground or in the background.

8. The method of claim 5 wherein determining where the window resides on the desktop further comprises determining the percentage of the window that is visible.

9. The method of claim 5 wherein determining what image content resides within the window further comprises determining whether the image content contains motion.

10. The method of claim 5 wherein determining what image content resides within the window further comprises determining whether the image content contains continuous-tone imagery.

11. The method of claim 5 wherein determining what image content resides within the window further comprises determining whether the image content is not in motion relative to the display.

12. The method of claim 5 wherein determining what image content resides within the window further comprises determining whether the image content contains live video.

13. The method of claim 5 wherein determining what image content resides within the window further comprises determining the size of the window in relationship to the size of the desktop.

14. A machine readable medium having embodied thereon instructions, which when executed by a machine, comprises:
assigning a priority level to a window in a windows-based environment; and
compressing the image data residing in the window if the priority level of the window falls below a predetermined threshold priority level.

15. The machine readable medium of claim 14 wherein compressing the image data residing in the window further comprises:
measuring the memory bandwidth requirement for a device where the windows-based environment resides; and
compressing image data only if the memory bandwidth requirement for the device cannot be met using uncompressed image data for all currently open windows.

16. The machine readable medium of claim 14 wherein compressing the image data residing in the window further comprises adjusting the compression ratio of the image data according to the image quality priority level.

17. The machine readable medium of claim 14 wherein compressing the image data residing in the window further comprises adjusting the compression ratio of the image data according to the displayed resolution of the window.

18. The machine readable medium of claim 14 wherein assigning a priority level to a window further comprises:
determining where the window resides on the desktop;
determining what image content resides within the window; and
setting a priority level for the window based on the determinations.

19. A system, comprising:
a bus;
a processor coupled to the bus;
a graphics card coupled to the bus; and
memory coupled to the processor, the memory adapted for storing instructions, which upon execution by the processor assign a priority level to a window in a windows-based environment and compress the image data residing in the window if the priority level of the window falls below a predetermined threshold priority level.

20. The system of claim 19 wherein compressing the image data residing in the window further comprises:
measuring the memory bandwidth requirement for a device where the windows-based environment resides; and
compressing image data only if the memory bandwidth requirement for the device cannot be met using uncompressed image data for all currently open windows.

21. The system of claim 19 wherein compressing the image data residing in the window further comprises adjusting the compression ratio of the image data according to the image quality priority level.

22. The system of claim 19 wherein compressing the image data residing in the window further comprises adjusting the compression ratio of the image data according to the displayed resolution of the window.

23. The system of claim 19 wherein assigning a priority level to a window further comprises:
determining where the window resides on the desktop;
determining what image content resides within the window; and
setting a priority level for the window based on the determinations.

24. The system of claim 23 wherein determining where the window resides on the desktop further comprises determining whether the window is the active window or an inactive window.

25. The system of claim 23 wherein determining where the window resides on the desktop further comprises determining whether the window is located in the foreground or in the background.

26. The system of claim 23 wherein determining where the window resides on the desktop further comprises determining the percentage of the window that is visible.

27. The system of claim 23 wherein determining what image content resides within the window further comprises determining whether the image content contains motion.

28. The system of claim 23 wherein determining what image content resides within the window further comprises determining whether the image content contains continuous-tone imagery.

29. The system of claim 23 wherein determining what image content resides within the window further comprises determining whether the image content is not in motion relative to the display.

30. The system of claim 23 wherein determining what image content resides within the window further comprises determining whether the image content contains live video.

31. The system of claim 23 wherein determining what image content resides within the window further comprises determining the size of the window in relationship to the size of the desktop.
